(19) United States
(12) Patent Application Publication
(10) Pub. No.: US 2001/0018168 A1
(43) Pub. Date: Aug. 30, 2001

(54) Resist development method

(75) Inventors: Nobue Kosa, Tokyo (JP); Yuji Shimizu, Tokyo (JP)

Correspondence Address: Norman P. Soloway, HAYES, SOLOWAY, HENNESSEY, GROSSMAN & HAGE, P.C., 175 Canal Street, Manchester, NH, 03101, US

(73) Assignee: NEC Corporation

(21) Appl. No.: 09/789,857

(22) Filed: Feb. 21, 2001

(30) Foreign Application Priority Data
Feb. 25, 2000 (JP) 49134/2000

(51) Int. Cl. G03F 7/30

(52) U.S. Cl. 430/329

(57) ABSTRACT

The resist development method of the present invention includes a step of applying a resist film to a wafer substrate, a step of exposing the resist film in a prescribed pattern, a step of removing the exposed part of the resist film with an alkaline liquid, and a step of cleaning the patterned resist film with ozone water.

### BACKGROUND OF THE INVENTION

1. Field of the Invention

The present invention relates to a resist development method, especially to a resist development method capable of preventing adhesion of a resist and a mixture of a developer and a resist to a resist pattern.

2. Description of the Prior Art

In order to increase the resolution of a chemically amplified resist, conventional resist development methods include a method for keeping the difference of the dissolution speeds high between an exposed part and an unexposed part of a resist film applied to a semiconductor wafer. The resist provided with a high resolution in this way has enhanced hydrophobicity in the unexposed part. In a conventional resist development method, the exposed part has been removed by an alkaline developer. In this case, if cleaning with a nonionic water is adopted after the removal, the dissolved resist, the alkaline developer, the nonionic water, and their mixture are not completely washed out and adhere to the unexposed part of the resist to cause defects.

In order to solve such a problem, for example, Japanese Patent Laid-Open No. 9-219385 (hereinafter referred to as a conventional example) discloses a technique in which a diluted acid solution is used in a rinsing treatment after separation of a photoresist film with an alkaline organic solution to avoid corrosion of the wiring owing to remaining alkali.

In the above described case of removing the exposed part by the alkaline developer, if cleaning with nonionic water after the removal is employed, the dissolved resist, the alkaline developer, the nonionic water, and their mixture are not completely washed out and adhere to the unexposed part of the resist to cause defects. Further, in the above mentioned conventional example, there occurs a problem in the neutralization technique using the diluted acid solution.

An object of the present invention is to solve such problems and to provide a resist development method and a resist development apparatus capable of avoiding adhesion of a resist, a mixture of a developer and a resist, and the likes to a resist pattern.

### BRIEF SUMMARY OF THE INVENTION

Object of the Invention

An object of the present invention is to provide a resist development method capable of avoiding adhesion of a resist, a mixture of a developer and a resist, and the likes to a resist pattern.

Summary of the Invention

The resist development method of the present invention comprises a step of applying a resist film on a wafer substrate, a step of exposing the resist film in a prescribed pattern, a step of removing the exposed part of the resist film with an alkaline liquid, and a step of cleaning the patterned resist film with ozone water.

### BRIEF DESCRIPTION OF THE DRAWINGS

The above-mentioned and other objects, features and advantages of the present invention will become more apparent by reference to the following detailed description of the invention taken in conjunction with the accompanying drawings, wherein:

FIG. 1 is a flow diagram illustrating a first embodiment of the present invention;

FIG. 2 is a block diagram of an apparatus for carrying out the operation shown in FIG. 1;

FIG. 3A to FIG. 3C are cross-sectional views illustrating the treatment steps shown in FIG. 1 on a wafer substrate;

FIG. 4 is a block diagram of an apparatus for producing ozone water shown in FIG. 2;

FIG. 5A and FIG. 5B are graphs illustrating the effects of the treatment by apparatus shown in FIG. 4; and

FIG. 6 is a graph illustrating the effects of the present invention.

### DETAILED DESCRIPTION OF THE PREFERRED EMBODIMENTS

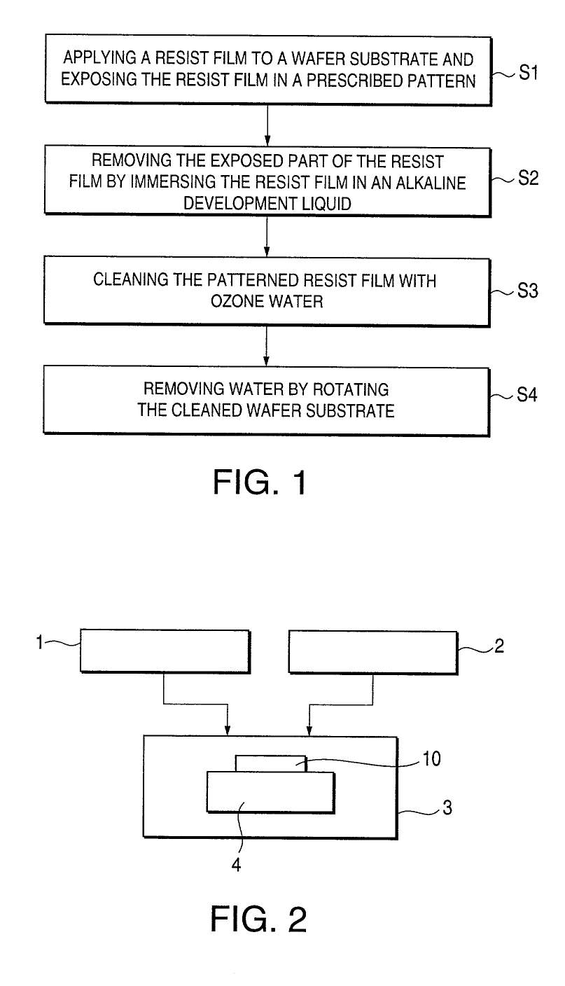

The present invention will be described in detail with reference to FIGS. FIG. 1 is a flow diagram of a resist development method illustrating a first embodiment of the present invention. At first, in the step S1, a resist film is applied to a semiconductor wafer substrate (10) by a common treatment technique, exposed in a prescribed pattern, and then subjected to post-exposure heating treatment. Secondarily, in the step S2, a developer is mounted on the resultant resist film subjected to the exposure and the post-exposure heating treatment to dissolve the exposed part of the resist film made soluble by the chemical reactions caused by the exposure and the post-exposure heating treatment with the alkaline liquid. Next, in the step S3, ozone water is dropped on the developed pattern of the resist film to clean the resist film pattern. Further, in the step S4, the cleaned wafer substrate is installed in an adsorption and rotation apparatus and rotated to remove the developer, the dissolved resist, and their mixture from the wafer substrate and clean the resist pattern.

Although the ozone concentration of the ozone water used in the cleaning is controlled to be about 15 ppm, even the ozone water with the lower concentration (as low as about 5 ppm) is effective. The ozone concentration is preferably within a range from 5 ppm to 20 ppm. In short, the cleaning effect is supposed to depend on the relation between the ozone water concentration and the treatment duration, so that the similarly high effect can be achieved by taking the treatment duration long even if the ozone concentration is thin.

FIG. 2 is a block diagram of a resist development apparatus used in this embodiment. The apparatus comprises an alkaline developer supply apparatus 1 for removing the exposed part with an alkaline developer after the exposure of a resist film applied to a wafer substrate 10, an ozone water supply apparatus 2 for cleaning the resist film removed with the alkaline developer off the wafer substrate 10 with ozone water, and a wafer treatment apparatus 3 comprising an adsorption and rotation apparatus 4 for adsorbing and rotating the wafer substrate 10.

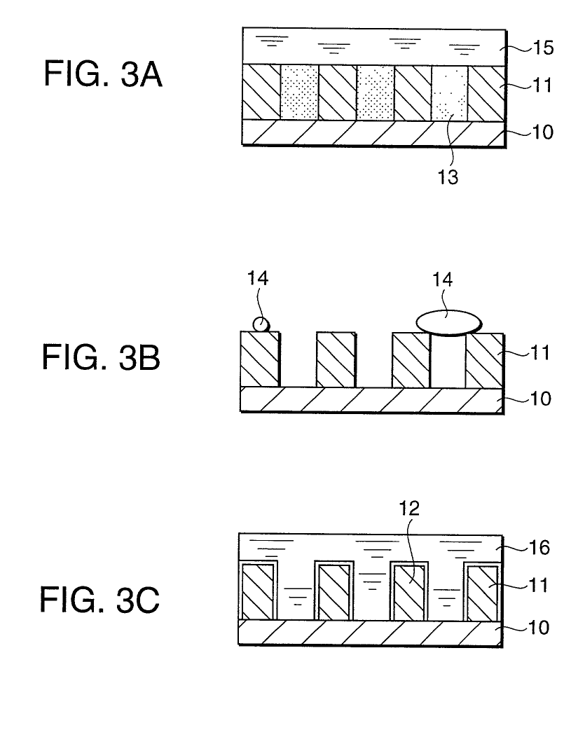

FIG. 3A to FIG. 3C are cross-sectional views illustrating the treatment states of the wafer substrate 10 of this embodiment in the order of treatment steps. At first, FIG. 3A shows the state where a hydrophobic resist 11 is applied to the wafer substrate 10, the resist 11 is exposed in a prescribed pattern, and the resist 11 is dissolved by applying the alkaline developer 15. In this case, the dissolved resist 13 remains among the hydrophobic resist 11. In such a situation, as being shown in FIG. 3B, although the alkaline developer 15 is removed, a resist mixture 14 containing the dissolved resist 13 and the alkaline developer 15 remains in the hydrophobic resist 11 on the substrate 10. Therefore, as being shown in FIG. 3C, ozone water 16 is dropped on the resist 11 containing the remaining resist mixture 14 to wash out the remaining resist mixture. In this case, since the resist surface 12 of the hydrophobic resist 11 is, as described below, made less hydrophobic and is provided with hydrophilicity owing to OH by the ozone water 16, the resist mixture 14 can be removed without adhering to the resist pattern.

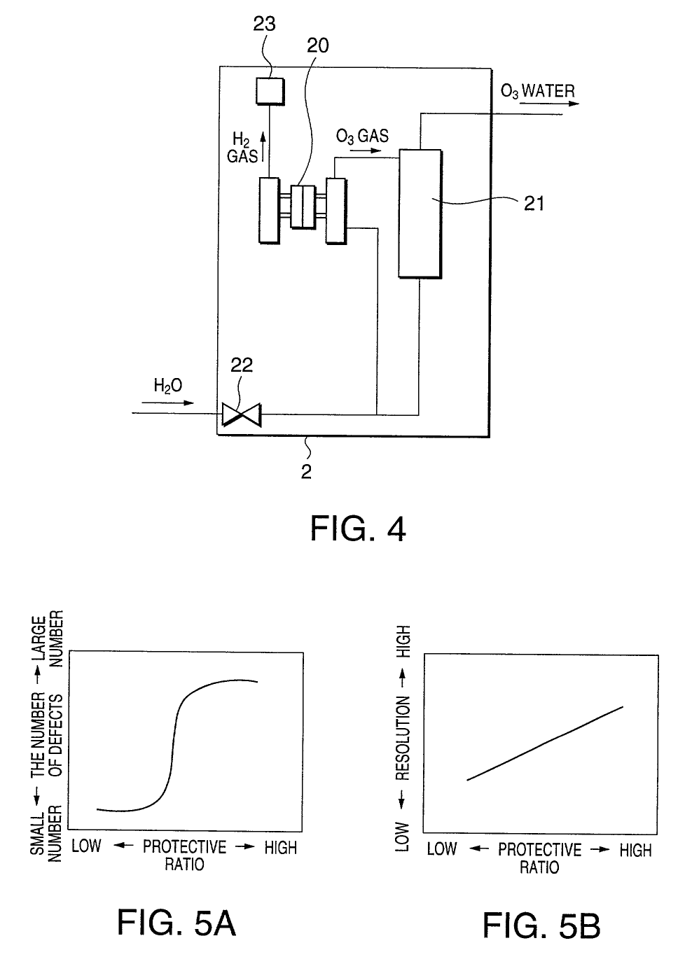

Incidentally, the commercially available ozone water production apparatus 2 adopt one of two methods, and both methods involve dissolving ozone (O₃) gas in water (H₂O) and are different in their dissolution manner. One involves the use of a dissolution module and FIG. 4 shows the apparatus structure. Through a gas dissolution membrane, O₃ gas is dissolved in H₂O. Since the gas dissolution membrane is impermeable to a liquid and is permeable only to a gas, O₃ gas is passed through the dissolution membrane and dissolved in H₂O by bringing H₂O and O₃ gas into contact with both sides of the membrane and by such a phenomenon, O₃-dissolved water can be produced. On the other hand, the other method is a so-called ejector method in which H₂O is pressurized by a pressure pump to produced vacuum state and then high concentration O₃ gas is introduced into the H₂O to mix O₃ in the H₂O.

Further, two methods are also available for producing O₃ gas. One is by electrolysis of H₂O. By general H₂O electrolysis, oxygen and hydrogen are produced, however by using an electrode catalyst and an electrolytic substance capable of generating O₃ gas instead of oxygen, O₃ gas can be produced instead of oxygen. The other method is by a silent discharge method for producing O₃ gas by passing oxygen between electrodes to which a.c. high voltage is applied.

FIG. 4 is a block diagram of one embodiment of an ozone water production apparatus 2. The apparatus 2 is for generating H₂ gas and O₃ gas by electrolysis of H₂O introduced through a valve 22 in the ozone generation part 20, burning H₂ gas in hydrogen combustion catalyst part 23, and dissolving O₃ gas in H₂O through the gas dissolution membrane by the ozone dissolution module 21.

In this embodiment, a developer is mounted on the resist film subjected to exposure and post-exposure heating treatment to dissolve the resist-exposed part made soluble by chemical reactions by the exposure and the post-exposure heating treatment with the alkaline liquid. Further, ozone water is dropped on the resultant developed resist pattern and then the wafer is rotated to remove the developer, the dissolved resist, and their mixture from the wafer.

In this case, the resist is patterned by being provided with a difference of dissolution speeds between the exposed part and the unexposed part by the chemical reactions by the exposure and the post-exposure heating treatment. Especially, a chemically amplified positive resist is made insoluble in an alkaline liquid by partially substituting polyhydroxystyrene, which is an alkali-soluble resin, with t-BOC (tert-butoxycarbonyl) with high hydrophobicity.

In detail, by exposure or by exposure and post-exposure heating treatment (PEB), the substituent group such as t-BOC is dissociated from polyhydroxystyrene and the part which is irradiated with light is made alkali-soluble. Generally, a KrF chemically amplified resist is composed of a resin with a protective group, an acid generating agent, and additives and the resist resin (PHS or polyhydroxystyrene) is hydrophilic owing to OH in the terminal (in the surface) and can be converted to a hydrophobic resist by substituting H with hydrophobic protective group t-BOC group in 20 to 40% in the whole resin.

The resist is applied to a wafer substrate, an acid is produced from the acid generating agent by the light for exposure and reacted with the protective group of the resin, and the protective group is dissociated from the resin. In such a manner, the part which is irradiated with the exposing light is made hydrophilic owing to dissociation of the protective group and the part which is not irradiated with the exposing light is kept hydrophobic as it is owing to the protective group. The part where the protective group is not dissociated is not dissolved in the developer and the part where the protective group is dissociated is dissolved. A resist image can thus be formed based on such dissolution contrast.

The characteristics of the protective group is 1) hydrophobicity and 2) dissociability from the resin by reaction with an acid. FIG. 5A and FIG. 5B are graphs illustrating the relation between the number of defects and the protective ratio and between the resolution and the protective ratio. That is, if the protective ratio is increased, the number of the defects is found sharply increased at a certain protective ratio or higher and in contrast with that, if the protective ratio is lower than the clarified certain ratio, the number of the defects is sharply decreased. On the other hand, the resolution is heightened more with the increase of the protective ratio and the resolution is linearly improved in proportion to the protective ratio. Consequently, by setting the protective ratio to be slightly smaller than the clarified certain value at which the number of the defects is sharply increased, the number of the defects can be lessened while the resolution being kept at a certain level.

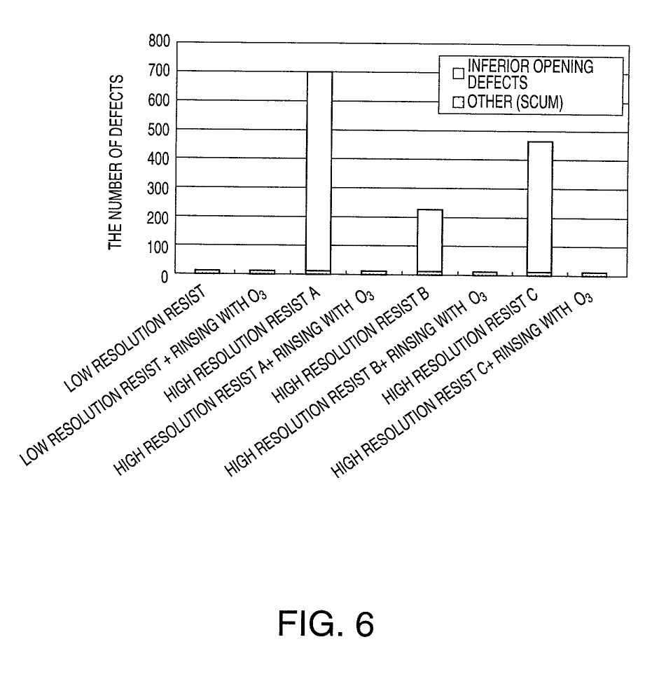

FIG. 6 is a graph of the difference of the number of defects by rinsing treatment with ozone water and illustrating the effects of the present invention. That is, the graph shows the results of investigation of the number of the inferior opening defects and the number of other defects, e.g. scum, in each case of using a low resolution resist and high resolution resists A, B, C, respectively, and carrying out rinsing treatment with ozone water or no rinsing treatment. In that investigation, in the case of using the low resolution resist, the number of inferior opening defects was as few as only one by both rinsing treatment with ozone water and no rinsing treatment with ozone water. On the other hand, in the case of using the high resolution resists A, B, C, the numbers of the inferior opening defects were 696, 230 and 451, respectively, if no rinsing treatment was carried out and these numbers of the inferior opening defects were decreased to be few; 2, 1 and 4, respectively; if rinsing treatment with ozone water was carried out. The number of other defects, such as scum or the like, was about 3 to 10 in all of the cases. Consequently, it was made clear that the rising treatment with ozone water was effective to decrease the inferior opening defects.

As described above, according to the present invention, since the exposed resist part of a resist film formed in a pattern is dissolved and then the dissolved resist is washed out with ozone water, the hydrophobicity of the surface layer of the resist is lowered and the dissolved resist, the alkaline developer, and their mixture can be removed without adhering to the resist pattern.

Although the invention has been described with reference to specific embodiments, this description is not meant to be construed in a limiting sense. Various modifications of the disclosed embodiments will become apparent to persons skilled in the art upon reference to the description of the invention. It is therefore contemplated that the appended claims will cover any modifications or embodiments as fall within the true scope of the invention.

What is claimed is:

1. A resist development method, comprising the steps of: applying a resist film to a wafer substrate, exposing said resist film in a prescribed pattern, removing the exposed part of said resist film with an alkaline liquid, and cleaning said patterned resist film with ozone water.

2. The resist development method according to claim 1, wherein ozone concentration of said ozone water is controlled to be within a range from 5 ppm to 20 ppm.

3. The resist development method according to claim 1, wherein said step of cleaning with ozone water is carried out by dropping ozone water on said resist film for cleaning.

4. The resist development method according to claim 1, wherein said resist development method further comprises a step of rotating said wafer substrate after said cleaning with ozone water.

5. The resist development method according to claim 1, wherein said resist film is a chemically amplified resist.
